(19) United States
(12) Patent Application Publication
(10) Pub. No.: US 2026/0122836 A1
(43) Pub. Date: Apr. 30, 2026

(54) AUTO-LOCK MECHANISM FOR FAN MODULES IN A COMPUTING SYSTEM

(71) Applicant: QUANTA COMPUTER INC., Taoyuan City (TW)

(72) Inventors: Yaw-Tzorng TSORNG, Taoyuan City (TW); Jen-Jia LIOU, Taoyuan City (TW); Wei-Jie CHEN, Taoyuan City (TW); Zuo-Jun YIN, Taoyuan City (TW)

(21) Appl. No.: 18/932,028

(22) Filed: Oct. 30, 2024

(51) Int. Cl. H05K 7/20; H05K 7/14

(52) U.S. Cl. CPC H05K 7/20172; H05K 7/1487; H05K 7/20727

(57) ABSTRACT

A computing system comprises a computing device having a housing. A cover is mounted to the housing and movable relative to the housing between an open position and a closed position. A hardware module such as a fan moule is removably inserted into the housing when the cover is in the open position. When the cover is in the closed position, the hardware module is enclosed within the housing. A slide lock is mounted on the hardware module. The slide lock is movable from an unlocked position to a locked position when the cover moves from the open position to the closed position and exerts a force on the slide lock. When the cover is removed from the housing, the slide lock automatically unlocks the hardware module so that the hardware module can be removed from the housing.

### FIELD OF THE INVENTION

The present invention relates generally to a computing system, and more specifically, to an auto-lock mechanism for efficiently installing and securing a hardware module in a computing system.

### BACKGROUND OF THE INVENTION

Computing systems, such as servers, are usually used in network-based data centers. Data centers have numerous application servers and storage servers used to store data and run applications accessed by various computer device users. Each server generally includes hardware components such as processors, memory devices, network interface cards, power supplies, cooling fans, and other specialized hardware components. These computing systems typically have structures for the installation and secure attachment of hardware modules including fan modules. The compact designs of the computing systems, however, normally result in space limitations within the structures. Consequently, these structures, together with the use of conventional fasteners for the hardware modules, such as thumb screws and hinge plungers, have made system assembly, especially the hardware module installation, difficult and inefficient. The installation process can even cause damages to hardware and finger cuts and/or lacerations to assembly personnel.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system includes a computing device. The computing device has a housing that defines a cavity. A cover is mounted to the housing and movable relative to the housing between an open position and a closed position. A hardware module is configured to fit into the cavity of the computing device. The hardware module is insertable into or removable from the cavity when the cover is in the open position. Additionally, the hardware module is enclosed within the housing when the cover is in the closed position. Further, a slide lock is exteriorly mounted on the hardware module. The slide lock is movable from an unlocked position to a locked position in response to receiving a locking force exerted by the cover when the cover moves from the open position to the closed position. Further, the unlocked position of the slide lock corresponds to the open position of the cover, and the locked position of the slide lock corresponds to the closed position of the cover.

According to a configuration of the above implementation, the slide lock is movable from the locked position to the unlocked position in response to removal of the locking force.

According to another configuration of the above implementation, the removal of the locking force is in response to moving the cover from the closed position to the open position.

According to yet another configuration of the above implementation, the cover includes a protrusion. Additionally, the protrusion is in contact with the slide lock when the cover moves from the open position to the closed position.

According to a further configuration of the above implementation, the cover is rotatably attached to the housing.

According to another configuration of the above implementation, the cover is attached to the housing along a rear edge of the cover.

According to yet another configuration of the above implementation, the computing system further comprises at least one other slide lock. The at least one other slide lock is disposed along a first lateral edge of the hardware module. The at least one other slide lock is disposed along a second lateral edge of the hardware module. The first lateral edge is generally parallel to and on an opposing side of the second lateral edge.

According to a further configuration of the above implementation, the housing defines a receiving slot and the slide lock includes a lock tab. The lock tab is inserted into the receiving slot of the housing when the slide lock is in the locked position. Moreover, the lock tab is separated from the receiving slot when the slide lock is in the unlocked position.

According to yet a further aspect of the above implementation, the slide lock includes a spring that is coupled to the lock tab. Additionally, the spring causes a spring force that slidably retracts the lock tab from the receiving slot when the cover moves from the closed position to the open position.

According to another aspect of the present disclosure, the computing system further comprises a bracket exteriorly mounted on the hardware module. The slide lock is mounted on the bracket.

According to a configuration of the above implementation, the hardware module is a fan module.

According to another configuration of the above implementation, the computing device is a server.

According to another aspect of the present disclosure, a computing system includes a computing device. The computing device has a housing that defines a cavity. A cover is mounted to the housing and is movable relative to the housing between an open position and a closed position. A hardware module is configured to fit into the cavity of the housing. The hardware module is insertable into or removable from the cavity when the cover is in the open position. Additionally, the hardware module is enclosed within the housing when the cover is in the closed position. A plurality of slide locks exteriorly is mounted on the hardware module. Each of the plurality of slide locks is movable from an unlocked position to a locked position in response to receiving a locking force exerted by the cover that is moved from the open position to the closed position. The unlocked position of each of the plurality of slide locks corresponds to the open position of the cover, and the locked position of each of the plurality of slide locks corresponds to the closed position of the cover.

According to a configuration of the above implementation, each of the plurality of slide locks is movable from the locked position to the unlocked position in response to removal of the locking force.

According to another configuration of the above implementation, the removal of the locking force is in response to moving the cover from the closed position to the open position.

According to a further aspect of the above implementation, the cover includes a plurality of protrusions. Each of the plurality of protrusions is in contact with a corresponding one of the plurality of slide locks, when the cover moves from the open position to the closed position.

In yet another aspect of the above implementation, the cover is rotatably attached to the housing.

In yet a further aspect of the above implementation, the cover is attached to the housing along a rear edge of the cover.

In yet a further aspect of the above implementation, the housing defines a plurality of receiving slots. Each of the plurality of slide locks has a lock tab. The lock tab of each of the plurality of slide locks is inserted into a corresponding one of the plurality of receiving slots, when each of the plurality of slide locks is in the locked position. The lock tab of each of the plurality of slide locks is separated from the corresponding one of the plurality of receiving slots, when each of the plurality of slide locks is in the unlocked position.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a perspective view showing a computing system with a cover being positioned at a closed position thereon, according to certain aspects of the present disclosure.

FIG. 2 is a perspective view showing a computing device of the computing system with the cover being positioned at an open position, according to certain aspects of the present disclosure.

FIG. 3 is a perspective view showing a hardware module of the computing system with the cover being removed from a housing of the computing device, according to certain aspects of the present disclosure.

FIG. 4 is a perspective view of the hardware module of the computing system, according to certain aspects of the present disclosure.

FIG. 5 is a front view of a slide lock mounted on a bracket of the computing system, according to certain aspects of the present disclosure.

FIG. 6 is a front view of at least one other slide lock mounted on at least one other bracket of the computing system, according to certain aspects of the present disclosure.

FIG. 7 is a front view of the slide lock being pressed into a locked position by a protrusion on the cover, according to certain aspects of the present disclosure.

FIG. 8 is a front view of the at least one other slide lock being pressed into the locked position by one of the plurality of protrusions, according to certain aspects of the present disclosure.

FIG. 9 is a perspective view showing a plurality of receiving slots defined by the housing of a computing device, according to certain aspects of the present disclosure.

### DETAILED DESCRIPTION

In the present disclosure, an auto-lock mechanism is presented for efficiently installing and securing a hardware module, such as a fan module, in a computing system. Instead of using thumb screws and/or hinge plungers, the auto-lock mechanism utilizes a slide lock mounted on the hardware module. When the hardware module is inserted into a housing of the computing system, the slide lock rests on a top edge of the housing. A cover closes the housing. While fully engaging with the top edge of the housing, the cover exerts a force on the slide lock. The resulting force causes the slide lock to slide from an unlocked position into a locked position, thus, securing the hardware module on the frame of the computing system.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

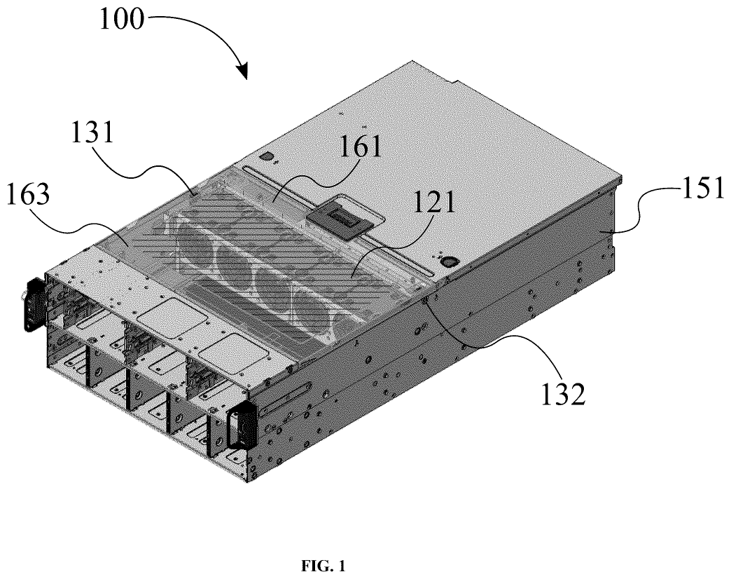

FIG. 1 shows a perspective view of a computing system 100 with a cover 161 being positioned at a closed position 163 thereon. Specifically, the computing system 100 comprises a hardware module 121, a slide lock 131, a computing device 151, and the cover 161. The cover 161 includes the closed position 163. The computing device 151 of the computing system 100 includes a server. The server can be either a storage server or an application server used in a network-based data center. The server generally includes hardware components such as processors, memory devices, network interface cards, power supplies, cooling fans, and other specialized hardware components. Servers generate an enormous amount of heat due to the operation of these electronic hardware devices. If not removed efficiently, the heat will accumulate and cause hazardous conditions to these devices. Thus, servers are designed to incorporate circulating air flows to effectively carry away the heat. Additionally, servers often include various heat sinks that are attached to the electronic components, such as processing units. Heat sinks are typically composed of thermally conductive material. Heat sinks absorb the heat from the electronic components, thus transferring the heat away from the components. The heat from heat sinks must be vented away from the server. Air flow to vent away such heat is often generated by a fan system, an example of the hardware module 121. The generated air flow carries collected heat away from the components and the heat sink. A good thermal design can assure the smallest fan power with limited air flow is sufficient to cool a fixed server. A typical fan system may include multiple fans. Such fans may be grouped together in a fan module to provide maximum cooling. Moreover, additional fans provide redundancy that allows for the operation of the server even if one of the fans in the fan module fails. Thus, the fan module, i.e., the hardware module 121, is a critical part of the computing device 151 to maintain a safe operating environment within the computing system 100.

As shown in FIG. 1, the slide lock 131 is exteriorly mounted on the hardware module 121. The hardware module 121 is attached to the computing device 151 via the slide lock 131. Additionally, the hardware module 121 is positioned within the computing device 151. The cover 161 encloses the computing system 100 when the cover 161 is at the closed position 163. Thus, the cover 161 maintains contact with the slide lock 131 to secure the hardware module 121 on the computing device 151. At the closed position 163, the cover 161 encloses the hardware module 121 within the computing device 151. The cover 161 forces the slide lock 131 to move downwards to engage with the computing device 151 to secure the hardware module 121 on the computing device 151.

In some implementations, the computing system 100 includes at least one other slide lock 132. The at least one other slide lock 132 is exteriorly mounted on the hardware module 121 opposite the slide lock 131. Additionally, the hardware module 121 of the computing system 100 includes, but is not limited to, a fan module, a middle fan module, or any other electronic module. Specifically, the middle fan module is an assembly of individual fans that are attached to a support structure. The fans are powered by the system and controlled by a baseboard management controller to provide airflow to the components of the computing system 100. Furthermore, the computing device 151 includes, but is not limited to, a server, a switch, a storage device, a router, a workstation, and any other suitable apparatus or device.

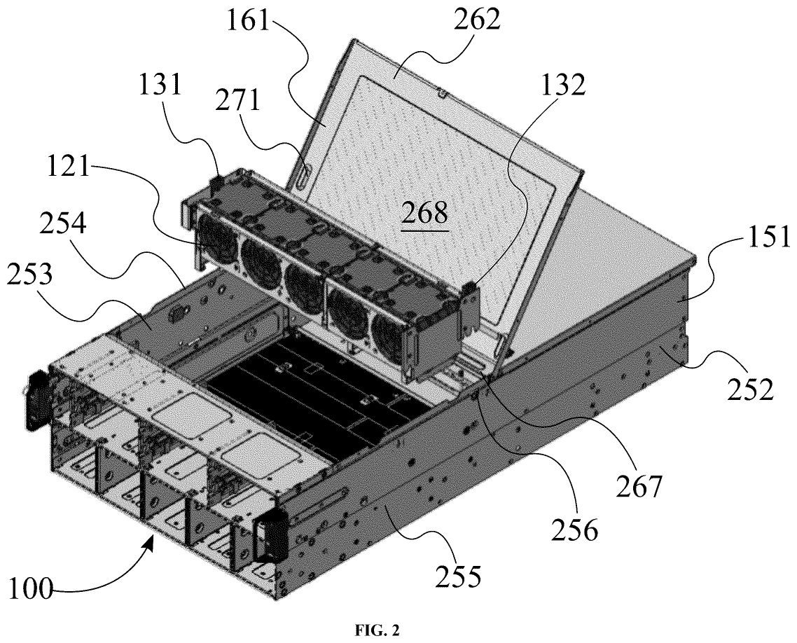

FIG. 2 shows a perspective view of the computing device 151 of the computing system 100 with the cover 161 being positioned at an open position 262. The computing device 151 of the computing system 100 includes a housing 252, a cavity 253, a first wall 254, and a second wall 255. Each of the first wall 254 and the second wall 255 defines a receiving slot 256. The receiving slot 256 receives a corresponding one of the slide lock 131 and the at least one other slide lock 132. Additionally, the housing 252 defines the cavity 253. The housing 252 and the cavity 253 are configured to provide a structure for desired components and/or substructures to be installed in the computing system 100.

As shown in FIG. 1 and FIG. 2, the cover 161 is mounted to the housing 252. The cover 161 further includes a rear edge 267, an interior surface 268, and a protrusion 271. Additionally, the cover 161 is configured to be movable relative to the housing 252 between the open position 262 and the closed position 163. When moved to the open position 262, the cover 161 opens the cavity 253 to allow the hardware module 121 and any other component to be inserted and installed to the computing device 151. When moved to the closed position 163, on the other hand, the cover 161 encloses the cavity 253 and electronic components within the computing device 151. The cover 161 is rotatably attached to the housing 252 along the rear edge 267, as shown in FIG. 2. Furthermore, the cover 161 has a substantially planar body and is made of a material, including, but not limited to, metal, sheet metal, plastic, polymer, any other suitable material, and any combination thereof.

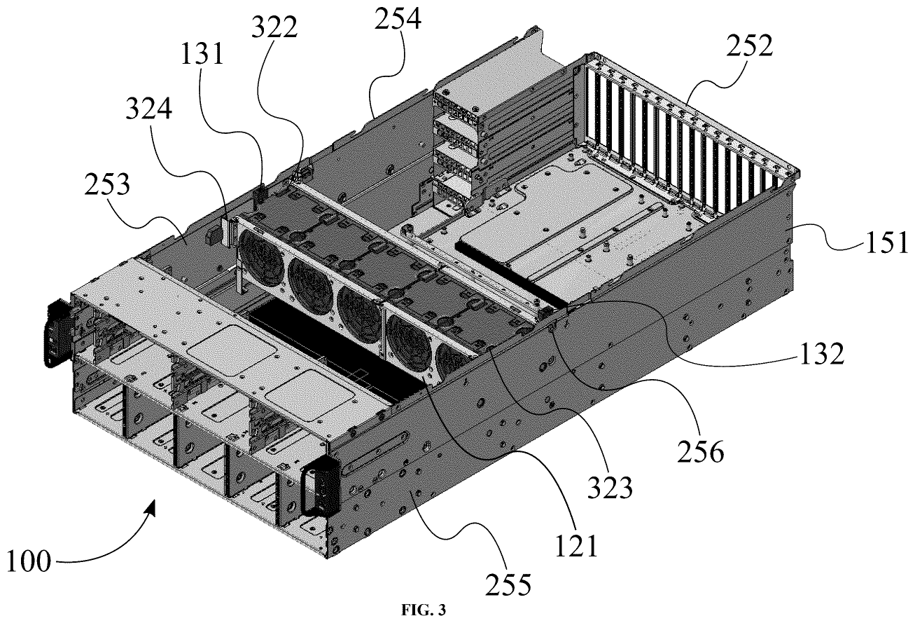

FIG. 3 shows a perspective view of the hardware module 121 of the computing system 100 with the cover 161 being removed from the housing 252. The hardware module 121 includes a first lateral edge 322 and a second lateral edge 323. The hardware module 121 is configured to fit into the cavity 253 of the computing device 151. In this example, the hardware module 121 is a middle fan module that extends across the cavity 253 to generate an air flow in the cavity 253 to cool components within the computing device 151. Thus, the hardware module 121 is insertable into or removable from the cavity 253 when the cover is removed, and/or in the open position 262, as shown in FIG. 2. Moreover, the hardware module 121 is enclosed within the housing 252 when the cover 161 is at the closed position 163, as shown in FIG. 1. Further, the hardware module 121 includes a bracket 324. The bracket 324 is mounted on the first lateral edge 322 of the hardware module 121, as shown in FIG. 3.

As shown in FIG. 2 and FIG. 3, the housing 252 of the computing device 151 includes the first wall 254 and the second wall 255. The first wall 254 is disposed on the housing 252 and substantially parallel to the second wall 255. Additionally, the first wall 254 is positioned opposite the second wall 255 across the cavity 253. Each of the first wall 254 and the second wall 255 includes the receiving slot 256. The receiving slot 256 is disposed on the housing 252 adjacent to the cover 161 when the cover is positioned at the closed position 163, as shown in FIG. 1.

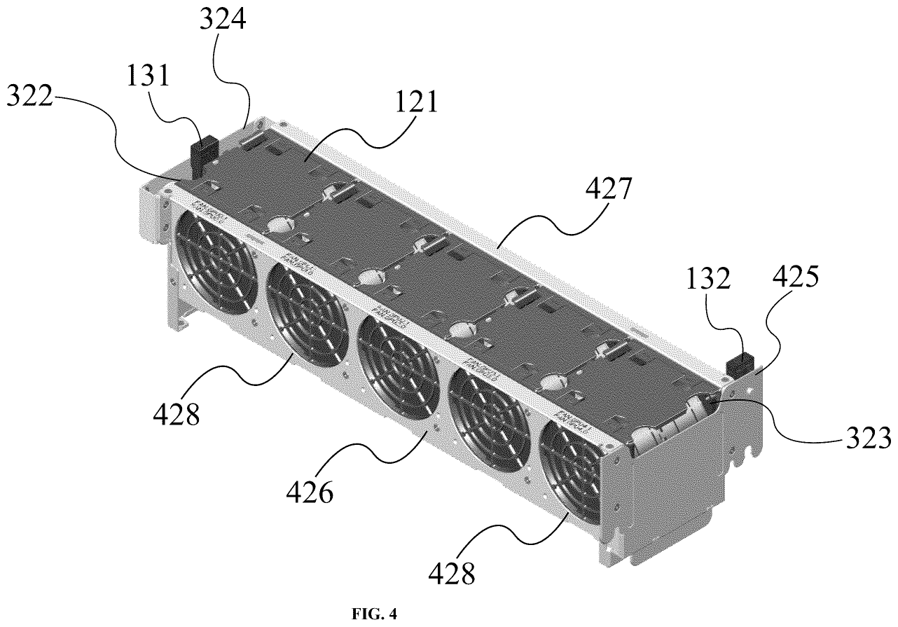

FIG. 4 shows a perspective view of the hardware module 121 of the computing system 100. The hardware module 121 includes the first lateral edge 322 and the second lateral edge 323. The first lateral edge 322 is positioned on an opposing side of the second lateral edge 323. The first lateral edge 322 is positioned generally parallel to the second lateral edge 323. In some implementations, the hardware module 121 is a middle fan module. A front plate 426 and a back plate 427 are attached to opposite ends of the first lateral edge 322 and the second lateral edge 323, respectively. A plurality of fans 428 are held between the front plate 426 and the back plate 427. Each of the plurality of fans 428 can be removed and replaced in the middle fan module 121. Further, the first lateral edge 322 is positioned adjacent and parallel to the first wall 254. The second lateral edge 323 is positioned adjacent to and parallel to the second wall 255.

As shown in FIG. 4, the computing system 100 further includes the bracket 324 and at least one other bracket 425. The bracket 324 and the at least one other bracket 425 are exteriorly mounted on the hardware module 121. In this example, the slide lock 131 is exteriorly disposed on the hardware module 121 along the first lateral edge 322. Additionally, the at least one other slide lock 132 is exteriorly disposed on the hardware module 121 along the second lateral edge 323. Further, the slide lock 131 is mounted on the bracket 324, and the at least one other slide lock 132 is mounted on the at least one other bracket 425.

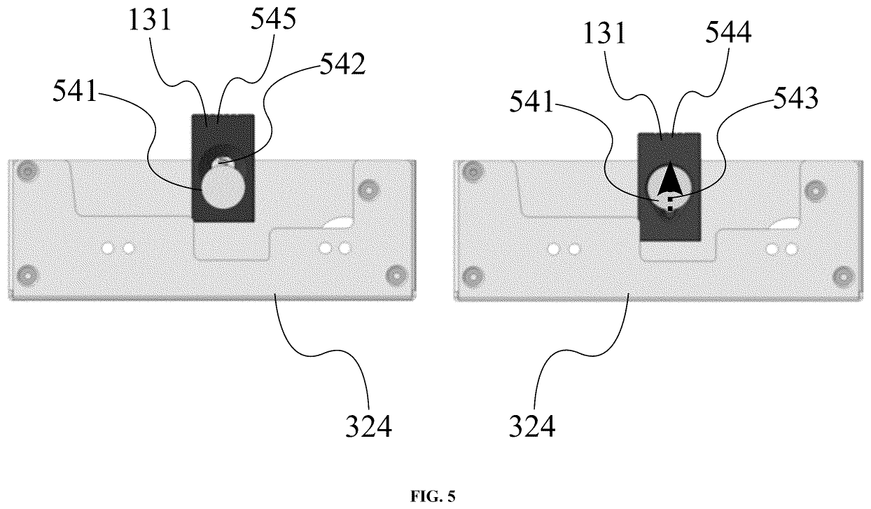

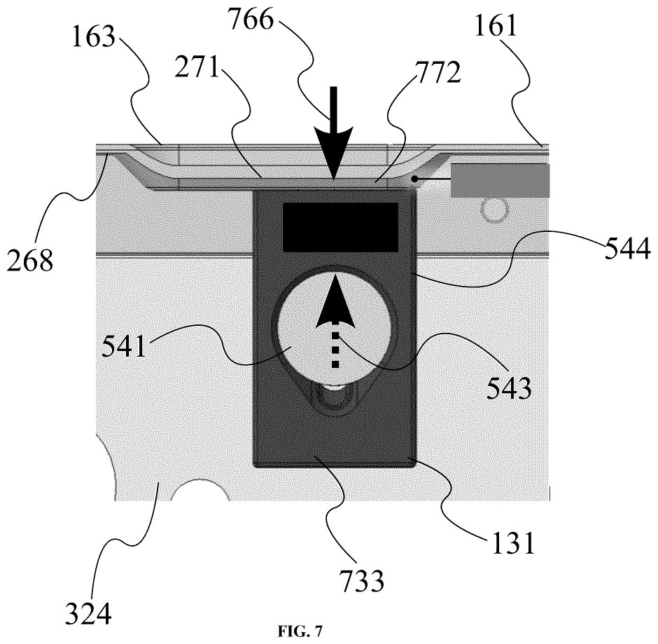

FIG. 5 shows a front view of the slide lock 131 mounted on the bracket 324. The slide lock 131 is configured to be movable from an unlocked position 545 to a locked position 544. Specifically, the slide lock 131 moves to the locked position 544 in response to receiving a locking force 766 exerted by the cover 161, as shown in FIG. 7. In this example, the locking force 766 is exerted when the cover 161 moves from the open position 262 to the closed position 163, as shown in FIG. 1, FIG. 2, and FIG. 7. Additionally, when the cover 161 is moved to the open position 262, the locking force 766 is released and the slide lock 131 automatically moves to the unlocked position 545, as shown in FIG. 2 and FIG. 5. Thus, the unlocked position 545 of the slide lock 131 corresponds to the open position 262 of the cover 161. Further, the locked position 544 of the slide lock 131 corresponds to the closed position 163 of the cover 161. The locking force 766 exerted on the slide lock 131 by the cover 161 maintains the slide lock 131 at the locked position 544, as shown in FIG. 1. FIG. 5, and FIG. 7. As long as the cover 161 stays at the closed position 163 on the housing 252, the slide lock 131 secures the hardware module 121 on the computing device 151. The slide lock 131 is movable from the locked position 544 to the unlocked position 545 in response to the removal of the locking force 766. The locking force 766 is removed in response to the cover 161 being moved from the closed position 163 to the open position 262, as shown in FIG. 1, FIG. 2 and FIG. 7.

As shown in FIG. 5, the slide lock 131 includes a lock tab 541, a spring 542, the locked position 544, and the unlocked position 545. As described above, the cover 161 forces the slide lock 131 within the cavity 253 of the computing device 151 when the cover 161 moves from the open position 262 to the closed position 163. At the closed position 163, the cover 161 compresses the slide lock 131 and thus compressing the spring 542 of the slide lock 131. Being compressed, the spring 542 generates a spring force 543. The spring force 543 causes the lock tab 541 to move downwardly to engage with housing 252. Thus, the hardware module 121 is secured on the computing device 151, under the cover 161. Further, the slide lock 131 is movable from the unlocked position 545 to the locked position 544 in response to receiving the locking force 766 exerted by the cover 161, as shown in FIG. 1, FIG. 5, and FIG. 7. When the cover 161 is removed from the computing device 151, i.e., moving from the closed position 163 to the open position 262, the spring force 543 is released, thus causing the lock tab 541 to disengage from the housing 252 of the computing device 151. This spring force 543 automatically releases the hardware module 121 from the housing 252.

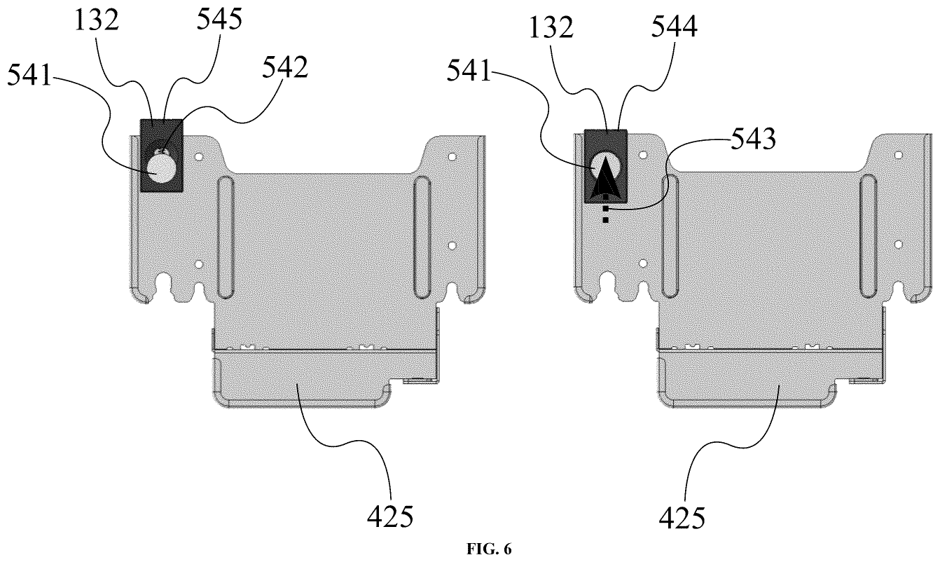

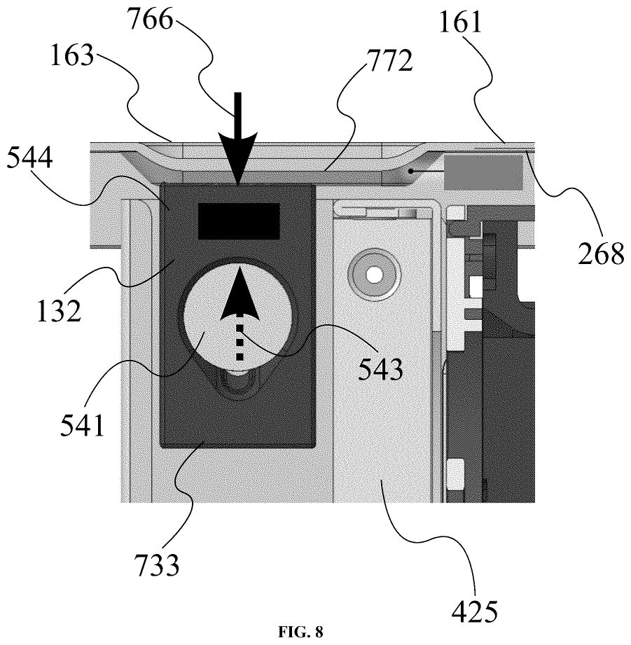

FIG. 6 shows a front view of at least one other slide lock 132 mounted on at least one other bracket 425. The at least one other slide lock 132 includes the lock tab 541, the spring 542, the locked position 544, and the unlocked position 545. The at least one other slide lock 132 provides a spring force 543. The at least one other slide lock 132 functions substantially the same as the slide lock 131, as shown in FIG. 5. The at least one other slide lock 132 is movable from the unlocked position 545 to the locked position 544 in response to receiving the locking force 766 exerted by the cover 161, as shown in FIG. 1 to FIG. 2, and FIG. 8.

FIG. 7 shows a front view of the slide lock 131 being pressed into the locked position 544 by the protrusion 271 on the cover 161. The cover 161 includes the interior surface 268 and the protrusion 271. The interior surface 268 is positioned on the cover 161 adjacent the cavity 253 of the housing 252 when the cover 161 moves to the closed position 163, as shown in FIG. 1 to FIG. 2, and FIG. 7. The protrusion 271 extends from the interior surface 268 and is positioned to be in contact with the slide lock 131 when the cover 161 is at the closed position 163. The resulting locking force 766 compresses the spring 542 of the slide lock 131, thus engaging the slide lock 131 to move to the locked position 544, when the cover 161 moves from the open position 262 to the closed position 163, as shown in FIG. 1, FIG. 2, FIG. 4, FIG. 6, and FIG. 7.

FIG. 8 shows a front view of the at least one other slide lock 132 being pressed into the locked position 544 by one of a plurality of protrusions 772. The cover 161 includes the plurality of protrusions 772, as shown in FIG. 7 and FIG. 8. The plurality of protrusions 772 includes the protrusion 271, as shown in FIG. 2 and FIG. 7. Further, each of the plurality of protrusions 772 is and functions substantially the same as the protrusion 271.

As shown in FIG. 7 and FIG. 8, the computing system 100 comprises a plurality of slide locks 733. The plurality of slide locks 733 includes the slide lock 131, and/or the at least one other slide lock 132. Each of the plurality of slide locks 733 is and functions substantially the same as the slide lock 131 and/or the at least one other slide lock 132.

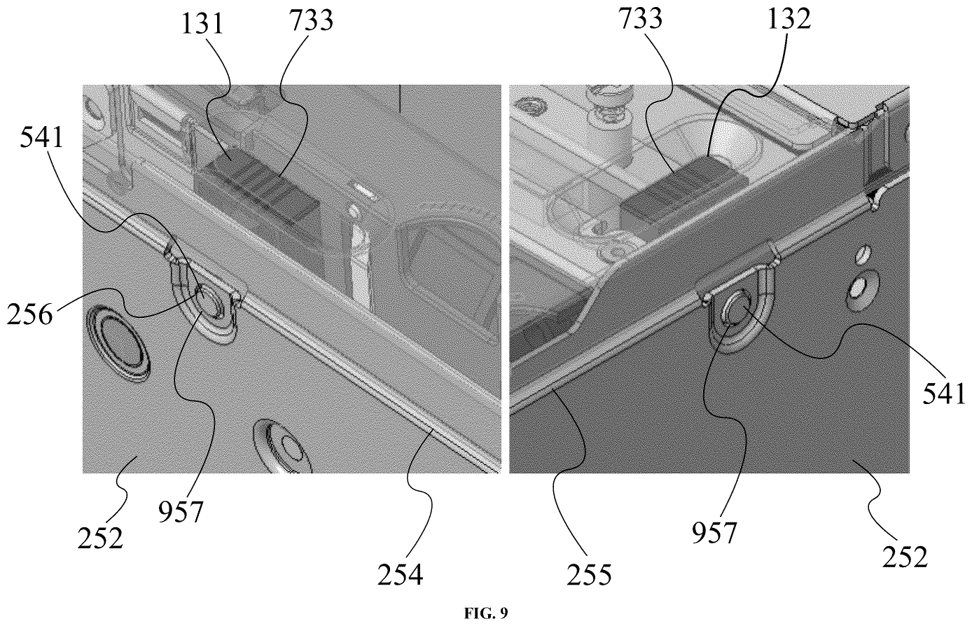

FIG. 9 is a perspective view of the housing 252 defining a plurality of receiving slots 957 of the computing device 151. The plurality of receiving slots 957 is defined by the housing 252 of the computing device 151, e.g., via either the first wall 254 or the second wall 255, as shown in FIG. 9. Each of the plurality of receiving slots 957 is configured to receive a corresponding one of the plurality of slide locks 733. Specifically, the lock tab 541 of each of the plurality of slide locks 733 is inserted into a corresponding one of the plurality of receiving slots 957, when each of the plurality of slide locks 733 is in the locked position 544, as shown in FIG. 7 to FIG. 9. Furthermore, the lock tab 541 of each of the plurality of slide locks 733 is separated from the corresponding one of the plurality of receiving slots 957, when each of the plurality of slide locks 733 is in the unlocked position 545, as shown in FIG. 5 and FIG. 6. The plurality of receiving slots 957 is and functions substantially the same as the receiving slot 256, as shown in FIG. 2 and FIG. 9. In some implementations, the plurality of receiving slots 957 includes the receiving slot 256.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system comprising:
a computing device including a housing, the housing defining a cavity;
a cover mounted to the housing, the cover being movable relative to the housing between an open position and a closed position;
a hardware module configured to fit into the cavity of the housing, the hardware module being insertable into or removable from the cavity when the cover is in the open position, the hardware module being enclosed within the housing when the cover is in the closed position; and
a slide lock exteriorly disposed on the hardware module, the slide lock being movable from an unlocked position to a locked position in response to receiving a locking force exerted by the cover when moving from the open position to the closed position, the unlocked position of the slide lock corresponding to the open position of the cover, the locked position of the slide lock corresponding to the closed position of the cover.

2. The computing system of claim 1, wherein the slide lock is movable from the locked position to the unlocked position in response to removal of the locking force.

3. The computing system of claim 2, wherein the removal of the locking force is in response to moving the cover from the closed position to the open position.

4. The computing system of claim 1, wherein the cover includes a protrusion, the protrusion being in contact with the slide lock when the cover moves from the open position to the closed position.

5. The computing system of claim 1, wherein the cover is rotatably attached to the housing.

6. The computing system of claim 5, wherein the cover is attached to the housing along a rear edge of the cover.

7. The computing system of claim 1, further comprising at least one other slide lock, the slide lock being disposed along a first lateral edge of the hardware module, the at least one other slide lock being disposed along a second lateral edge of the hardware module, the first lateral edge being generally parallel to and on an opposing side of the second lateral edge.

8. The computing system of claim 1, wherein the housing defines a receiving slot and the slide lock includes a lock tab, the lock tab being inserted into the receiving slot of the housing when the slide lock is in the locked position, the lock tab being separated from the receiving slot when the slide lock is in the unlocked position.

9. The computing system of claim 8 wherein the slide lock includes a spring, the spring being coupled to the lock tab, the spring causing a spring force that slidably retracts the lock tab from the receiving slot of the housing when moving the cover from the closed position to the open position.

10. The computing system of claim 1, further comprising a bracket exteriorly mounted on the hardware module, the slide lock being mounted on the bracket.

11. The computing system of claim 1, wherein the hardware module is a fan module.

12. The computing system of claim 1, wherein the computing device is a server.

13. A computing system comprising:
a computing device including a housing, the housing defining a cavity;
a cover mounted to the housing, the cover being movable relative to the housing between an open position and a closed position;
a hardware module configured to fit into the cavity of the housing, the hardware module being insertable into or removable from the cavity when the cover is in the open position, the hardware module being enclosed within the housing when the cover is in the closed position; and
a plurality of slide locks exteriorly disposed on the hardware module, each of the plurality of slide locks is movable from an unlocked position to a locked position in response to receiving a locking force exerted by the cover when moving from the open position to the closed position, the unlocked position of each of the plurality of slide locks corresponding to the open position of the cover, the locked position of each of the plurality of slide locks corresponding to the closed position of the cover.

14. The computing system of claim 13, wherein each of the plurality of slide locks is movable from the locked position to the unlocked position in response to removal of the locking force.

15. The computing system of claim 14, wherein the removal of the locking force is in response to moving the cover from the closed position to the open position.

16. The computing system of claim 13, wherein the cover includes a plurality of protrusions, each of the plurality of protrusions being in contact with a corresponding one of the plurality of slide locks, when the cover moves from the open position to the closed position.

17. The computing system of claim 13, wherein the cover is rotatably attached to the housing.

18. The computing system of claim 17, wherein the cover is attached to the housing along a rear edge of the cover.

19. The computing system of claim 13, wherein the housing defines a plurality of receiving slots, each of the plurality of slide locks having a lock tab, the lock tab of each of the plurality of slide locks being inserted into a corresponding one of the plurality of receiving slots, when each of the plurality of slide locks is in the locked position, and the lock tab of each of the plurality of slide locks being separated from the corresponding one of the plurality of receiving slots, when each of the plurality of slide locks is in the unlocked position.

20. The computing system of claim 19, wherein each of the plurality of slide locks includes a spring, the spring being coupled to the lock tab, the spring causing a spring force that slidably retracts the lock tab from the corresponding one of the plurality of receiving slots, when moving the cover from the closed position to the open position.
